(19) United States
(12) Patent Application Publication
(10) Pub. No.: US 2024/0413079 A1
(43) Pub. Date: Dec. 12, 2024

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Samki Kim, Suwon-si (KR); Nambin Kim, Suwon-si (KR); Taehun Kim, Suwon-si (KR)

(21) Appl. No.: 18/629,785

(22) Filed: Apr. 8, 2024

(30) Foreign Application Priority Data
Jun. 9, 2023 (KR) 10-2023-0074163

(51) Int. Cl. H01L 23/528; H01L 25/065; H01L 29/78; H10B 41/27; H10B 43/27; H10B 80/00

(52) U.S. Cl. CPC H01L 23/528; H01L 25/0657; H01L 29/7827; H10B 80/00; H10B 41/27; H10B 43/27

(57) ABSTRACT

The present disclosure relates to semiconductor devices, in which a semiconductor device includes: a plate layer, gate electrodes stacked and spaced apart from each other on the plate layer in a first direction, the gate electrodes including first gate electrodes and second gate electrodes on the first gate electrodes; a horizontal insulating layer between the first gate electrodes and the second gate electrode; first channel structures extending through the first gate electrodes in the first direction; second channel structures extending through the second gate electrodes in the first direction and electrically connected to the first channel structures, respectively; contact plugs extending through the horizontal insulating layer in the first direction and connected to the gate electrodes, respectively; dummy vertical structures extending through the horizontal insulating layer in the first direction and around the contact plugs, and a cell region insulating layer covering upper surfaces of the dummy vertical structures.

### CROSS-REFERENCE TO RELATED APPLICATION

This application claims benefit of priority to Korean Patent Application No. 10-2023-0074163 filed on Jun. 9, 2023, in the Korean Intellectual Property Office, the disclosure of which is incorporated herein by reference in its entirety.

### BACKGROUND

A semiconductor device able to store high-capacity data is needed in a data storage system. Accordingly, research has been conducted for a method for increasing data storage capacity of a semiconductor device. For example, as a method for increasing data storage capacity of a semiconductor device, a semiconductor device including memory cells disposed three-dimensionally, instead of memory cells disposed two-dimensionally, has been suggested.

### SUMMARY

The present disclosure relates to data storage systems and semiconductor devices, including semiconductor devices having improved reliability.

In general, according to some aspects, the subject matter of the present disclosure is directed to a semiconductor device that includes: a first semiconductor structure including a substrate, circuit devices on the substrate, and circuit interconnection lines on the circuit devices; and a second semiconductor structure on the first semiconductor structure and having first and second regions, wherein the second semiconductor structure includes a plate layer; gate electrodes including lower select gate electrodes, memory gate electrodes, and upper select gate electrodes stacked and spaced apart from each other in a first direction perpendicular to an upper surface of the plate layer on the plate layer and stacked in order from the plate layer; a horizontal insulating layer between the memory gate electrodes and the upper select gate electrode; first channel structures penetrating through the lower select gate electrode and the memory gate electrodes and extending in the first direction in the first region; connection pads penetrating through the horizontal insulating layer and connected to the first channel structures; second channel structures penetrating through the upper select gate electrode, connected to the connection pads, and electrically connected to the first channel structures, respectively, in the first region; contact plugs penetrating through at least a portion of the gate electrodes, extending in the first direction and electrically connecting the gate electrodes to a portion of the circuit interconnection lines in the second region; and dummy vertical structures around the contact plugs, penetrating through the horizontal insulating layer and extending in the first direction in the second region, and wherein lower ends of the dummy vertical structures are on a first level, and lower ends of the contact plugs are on a second level lower than the first level.

In general, according to some other aspects, the subject matter of the present disclosure is directed to a semiconductor device that includes: a plate layer; gate electrodes stacked and spaced apart from each other on the plate layer in a first direction perpendicular to an upper surface of the plate layer, and including first gate electrodes and second gate electrodes on the first gate electrodes; a horizontal insulating layer between the first gate electrodes and the second gate electrode and including nitride; first channel structures penetrating through the first gate electrodes and extending in the first direction; second channel structures penetrating through the second gate electrodes, extending in the first direction, and electrically connected to the first channel structures, respectively; contact plugs penetrating through the horizontal insulating layer, extending in the first direction, and connected to the gate electrodes, respectively; dummy vertical structures penetrating through the horizontal insulating layer and extending in the first direction around the contact plugs; and a cell region insulating layer covering upper surfaces of the dummy vertical structures.

In general, in some other aspects, the subject matter of the present disclosure is directed to a data storage system that includes: a semiconductor storage device including a first semiconductor structure including circuit devices, a second semiconductor structure on one surface of the first semiconductor structure, and an input/output pad electrically connected to the circuit devices; and a controller electrically connected to the semiconductor storage device through the input/output pad and controlling the semiconductor storage device, wherein the second semiconductor structure includes a plate layer; gate electrodes stacked and spaced apart from each other on the plate layer in a first direction perpendicular to an upper surface of the plate layer, and including first gate electrodes and second gate electrodes on the first gate electrodes; a horizontal insulating layer between the first gate electrodes and the second gate electrodes and including nitride; first channel structures penetrating through the first gate electrodes and extending in the first direction; second channel structures penetrating through the second gate electrodes, extending in the first direction, and electrically connected to the first channel structures, respectively; contact plugs penetrating through the horizontal insulating layer, extending in the first direction, and connected to the gate electrodes, respectively; dummy vertical structures penetrating through the horizontal insulating layer and extending in the first direction around the contact plugs; and a cell region insulating layer covering upper surfaces of the dummy vertical structures, wherein the dummy vertical structures include the same material as a material of the contact plugs and have a length different from a length of the contact plugs.

### BRIEF DESCRIPTION OF THE DRAWINGS

The above and other aspects, features, and advantages of the present disclosure will be more clearly understood from the following detailed description, taken in combination with the accompanying drawings.

FIGS. 1A and 1B are plan views illustrating an example of a semiconductor device.

FIGS. 2A and 2B are cross-sectional views illustrating an example of a semiconductor device.

FIGS. 3A to 3C are enlarged views illustrating a portion of an example of a semiconductor device.

FIGS. 4A to 4C are enlarged views illustrating a portion of another example of a semiconductor device.

FIGS. 5A and 5B are cross-sectional views illustrating another example of a semiconductor device.

FIG. 6 is a cross-sectional view illustrating another example of a semiconductor device.

FIGS. 7A to 7J are cross-sectional views illustrating an example of a method of manufacturing a semiconductor device.

FIG. 8 is a view illustrating an example of a data storage system including a semiconductor device.

FIG. 9 is a perspective view illustrating an example of a data storage system including a semiconductor device.

FIG. 10 is a cross-sectional view illustrating an example of a semiconductor package.

### DETAILED DESCRIPTION

Hereinafter, implementations of the present disclosure will be described as follows with reference to the accompanying drawings.

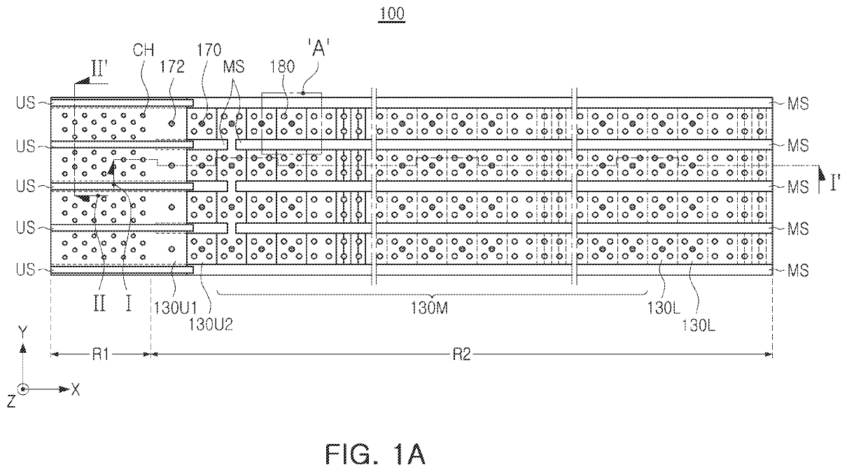

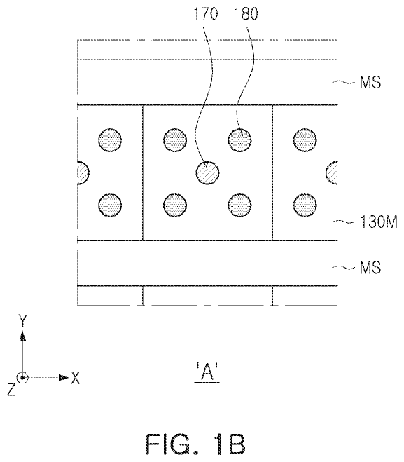

FIGS. 1A and 1B are plan views illustrating an example of a semiconductor device. FIG. 1B is an enlarged view illustrating “A” region in FIG. 1A.

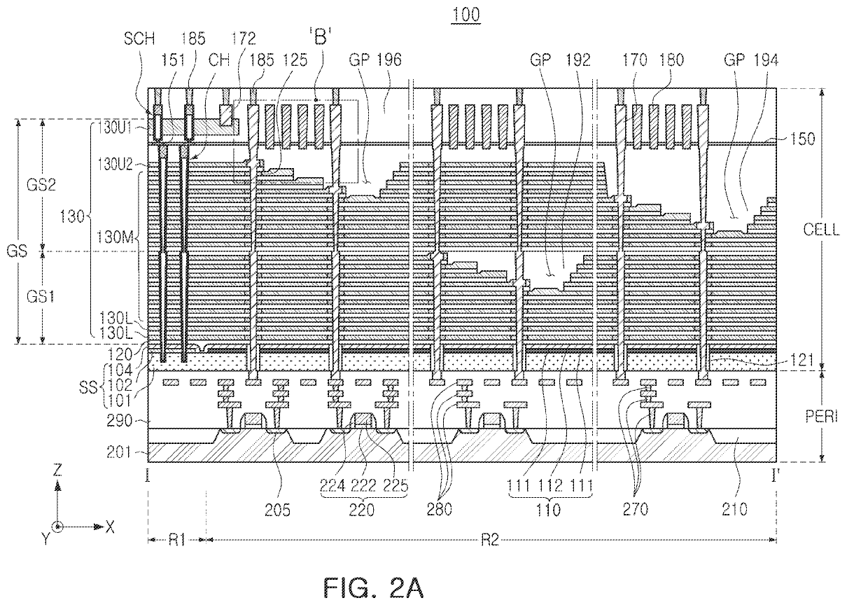

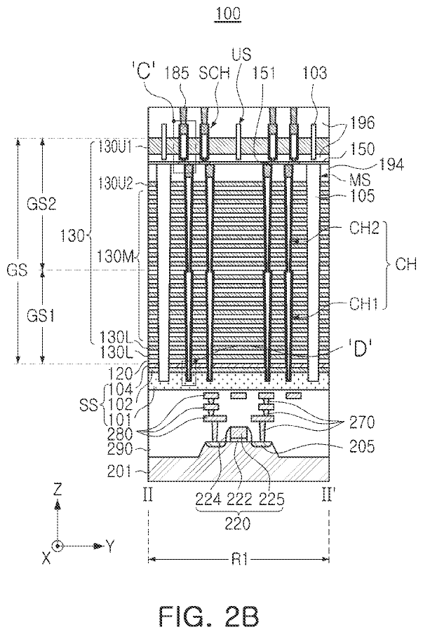

FIGS. 2A and 2B are cross-sectional views illustrating an example of a semiconductor device, taken along lines I-I′ and II-II′ in FIG. 1.

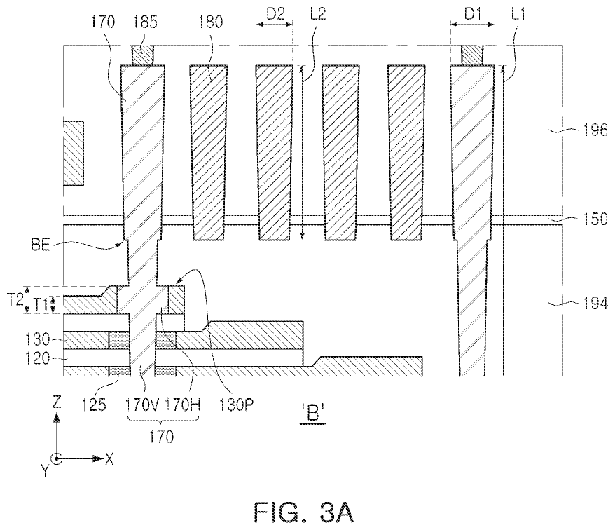

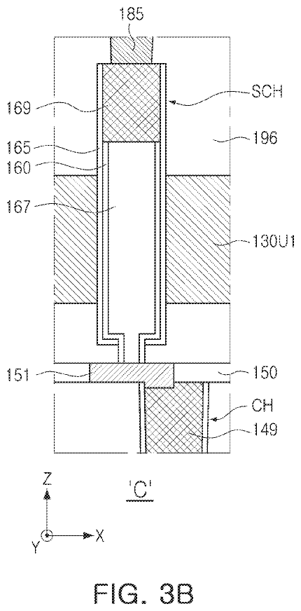

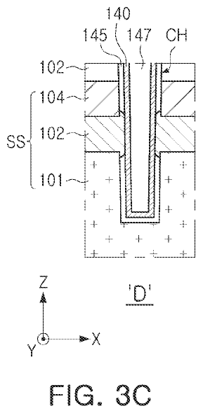

FIGS. 3A to 3C are enlarged views illustrating a portion of an example of a semiconductor device. FIG. 3A is an enlarged view illustrating “B” region in FIG. 2A, FIG. 3B is an enlarged view illustrating “C” region in FIG. 2B, and FIG. 3C is an enlarged view illustrating “D” region in FIG. 2B.

Referring to FIGS. 1A to 3C, a semiconductor device 100 includes a peripheral circuit region PERI, which is a first semiconductor structure including a substrate 201, and a memory cell region CELL, which is a second semiconductor structure including a plate layer 101. The memory cell region CELL may be disposed on the peripheral circuit region PERI. Conversely, in some implementations, the memory cell region CELL is disposed below the peripheral circuit region PERI.

The peripheral circuit region PERI may include a substrate 201, impurity regions 205 and device isolation layers 210 in the substrate 201, circuit devices 220 disposed on the substrate 201, a peripheral region insulating layer 290, circuit contact plugs 270, and circuit interconnection lines 280.

The substrate 201 may have an upper surface extending in the X-direction and the Y-direction. In the substrate 201, an active region may be defined by the device isolation layers 210. The impurity regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit devices 220 may include planar transistors. Each of the circuit devices 220 may include a circuit gate dielectric layer 222, a spacer layer 224 and a circuit gate electrode 225. On both sides of the circuit gate electrode 225, the impurity regions 205 may be disposed as source/drain regions in the substrate 201.

The peripheral region insulating layer 290 may be disposed on the circuit device 220 on the substrate 201. The peripheral region insulating layer 290 may include a plurality of insulating layers formed in different processes. The peripheral region insulating layer 290 may be formed of an insulating material.

The circuit contact plugs 270 and the circuit interconnection lines 280 may form a circuit interconnection structure electrically connected to the circuit devices 220 and the impurity regions 205. The circuit contact plugs 270 may have a cylindrical shape, and the circuit interconnection lines 280 may have a line shape. An electrical signal may be applied to the circuit device 220 by the circuit contact plugs 270 and the circuit interconnection lines 280. In a region not illustrated, circuit contact plugs 270 may also be connected to the circuit gate electrode 225. The circuit interconnection lines 280 may be connected to the circuit contact plugs 270, may have a line shape, and may be disposed in a plurality of layers. The circuit contact plugs 270 and the circuit interconnection lines 280 may include a conductive material, for example, tungsten (W), copper (Cu), aluminum (Al), and the like, and each component may further include a diffusion barrier. In some implementations, the number of layers of circuit contact plugs 270 and the circuit interconnection lines 280 are varied.

The memory cell region CELL may have first and second regions R1 and R2, and may include source structure SS, gate electrodes 130 stacked on the source structure SS and forming the gate structure GS, interlayer insulating layers 120 alternately stacked with the gate electrodes 130, first channel structures CH and second channel structures SCH disposed to penetrate through the gate structure GS in the first region R1, first isolation regions MS extending by partially penetrating through the gate structure GS, second isolation regions US penetrating through a portion disposed in an upper portion of the gate electrodes 130, a horizontal insulating layer 150 and connection pads 151 disposed between the first channel structures CH and the second channel structures SCH, contact plugs 170 connected to the gate electrodes 130 in the second region R2 and extending vertically, and dummy vertical structures 180 disposed around the contact plugs 170 and penetrating through the horizontal insulating layer 150. The memory cell region CELL may further include a horizontal sacrificial layer 110 disposed below the gate electrodes 130 in the second region R2, substrate insulating layers 121 disposed to penetrate through the plate layer 101, upper contact plug 172, studs 185 on the second channel structures SCH and the contact plugs 170, and first to third cell region insulating layers 192, 194, 196 covering the gate electrodes 130.

In the memory cell region CELL, in the first region R1, the gate electrodes 130 may be vertically stacked and the first channel structures CH may be disposed, and memory cells may be disposed in the first region R1. In the second region R2, the gate electrodes 130 may extend to different lengths, and the second region R2 may be configured to electrically connect the memory cells to the peripheral circuit region PERI. The second region R2 may be disposed on least one end of the first region R1 in at least one direction, for example, the X-direction.

The source structure SS may include a plate layer 101, a first horizontal conductive layer 102, and a second horizontal conductive layer 104 stacked in order in the first region R1. However, in some implementations, the number of conductive layers included in the source structure SS are varied.

The plate layer 101 may have a plate shape and may function as at least a portion of a common source line of the semiconductor device 100. The plate layer 101 may have an upper surface extending in the X-direction and the Y-direction. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be stacked in order on the upper surface of the plate layer 101 in the first region R1. The first horizontal conductive layer 102 may not extend to the second region R2, and the second horizontal conductive layer 104 may extend to the second region R2. The first horizontal conductive layer 102 may function as a portion of a common source line of the semiconductor device 100, and may function as a common source line together with the plate layer 101, for example. As illustrated in FIG. 3C, the first horizontal conductive layer 102 may be directly connected to the channel layer 140 around the channel layer 140. The second horizontal conductive layer 104 may be in contact with the plate layer 101 in partial regions of the second region R2 in which the first horizontal conductive layer 102 and the horizontal sacrificial layer 110 are not disposed.

The first and second horizontal conductive layers 102 and 104 may include a semiconductor material, such as polycrystalline silicon. In this case, at least the first horizontal conductive layer 102 may be doped with impurities having the same conductivity as that of the plate layer 101, and the second horizontal conductive layer 104 may be a doped layer or a layer including impurities diffused from the first horizontal conductive layer 102. However, the material of the second horizontal conductive layer 104 is not limited to a semiconductor material, and may be replaced with an insulating layer.

The horizontal sacrificial layer 110 may be disposed on the plate layer 101 on the same level as a level of the first horizontal conductive layer 102 in at least a portion of the second region R2. The horizontal sacrificial layer 110 may include first and second horizontal sacrificial layers 111 and 112 alternately stacked on the second region R2 of the plate layer 101. The horizontal sacrificial layer 110 may be layers remaining after a portion is replaced with the first horizontal conductive layer 102 in the process of manufacturing the semiconductor device 100.

The horizontal sacrificial layer 110 may include silicon oxide, silicon nitride, silicon carbide, or silicon oxynitride. The first horizontal sacrificial layers 111 and the second horizontal sacrificial layer 112 may include different insulating materials. For example, the first horizontal sacrificial layers 111 may be formed of the same material as that of the interlayer insulating layers 120, and the second horizontal sacrificial layer 112 may be formed of a material different from that of the interlayer insulating layers 120.

The substrate insulating layers 121 may be disposed to penetrate through the plate layer 101, the horizontal sacrificial layer 110, and the second horizontal conductive layer 104 in a portion of the second region R2. The substrate insulating layers 121 may be further disposed in the first region R1, and may be disposed in a region in which through-vias extending from the memory cell region CELL to the peripheral circuit region PERI are disposed, for example. An upper surface of the substrate insulating layer 121 may be coplanar with an upper surface of the second horizontal conductive layer 104. The substrate insulating layer 121 may include an insulating material such as silicon oxide, silicon nitride, silicon carbide, or silicon oxynitride.

The gate electrodes 130 may be vertically stacked and spaced apart from each other on the plate layer 101 and may form a gate structure GS together with the interlayer insulating layers 120. The gate structure GS may include first and second stack structures GS1 and GS2 which may be vertically stacked. However, in some implementations, the number of stack structures included in the gate structure GS are varied. For example, in some implementations, the gate structure GS includes three or more stack structures or may include a single stack structure. The number of gate electrodes 130 included in the first stack structure GS1 and the number of gate electrodes 130 included in the second stack structure GS2 may be the same or different.

The gate electrodes 130 may include a first upper gate electrode 130U1 forming string select transistors, a second upper gate electrode 130U2 forming an erase transistor, memory gate electrodes 130M forming a plurality of memory cells, lower gate electrodes 130L forming the erase transistor and the ground select transistor. The number of memory gate electrodes 130M included in the memory cells may be determined depending on capacity of the semiconductor device 100. In this specification, the second upper gate electrode 130U2, the memory gate electrodes 130M, and the lower gate electrodes 130L may be referred to as first gate electrodes, and the first upper gate electrode 130U1 may be referred to as a second gate electrode. The first upper gate electrode 130U1 and one of the lower gate electrodes 130L may also be referred to as an upper select gate electrode and a lower select gate electrode, respectively. In some implementations, each of the number of the first upper gate electrode 130U1, the number of the second upper gate electrode 130U2, and the number of the lower gate electrodes 130L are 1 to 4 or more, and may have a structure the same as or different from that of the memory gate electrodes 130M. In some implementations, the second upper gate electrode 130U2 and/or at least one lower gate electrodes 130L are not provided. A portion of the gate electrodes 130, for example, the memory gate electrodes 130M adjacent to the second upper gate electrode 130U2 or the lower gate electrodes 130L may be dummy gate electrodes.

The gate electrodes 130 may be vertically stacked and spaced apart from each other on the first region R1, and may extend to different lengths from the first region R1 to the second region R2 and may form step structures in a staircase form in the gate pad regions GP. As illustrated in FIG. 2A, the gate electrodes 130 may have a shape removed by a predetermined depth from an upper portion of one of first and second stack structures GS1 and GS2 in the gate pad regions GP. The gate pad regions GP may be disposed to not overlap each other in the Z-direction. On the gate pad region GP of the first stack structure GS1, at least a portion of the gate electrodes 130 included in the upper second stack structures GS2 may extend horizontally. In some implementations, the gate pad regions GP are disposed in order in the second stack structure GS2, the first stack structure GS1, and the second stack structure GS2 in the X-direction from the first region R1. However, in some implementations, the arrangement type, the arrangement order, and the depth of the gate pad regions GP are varied. In some implementations, the gate electrodes 130 are not disposed on the gate pad regions GP.

The gate electrodes 130 may form first and second step structures in an asymmetrical form in the X-direction in each gate pad region GP. The first step structure may be a staircase structure relatively adjacent to the first region R1 and may be a staircase structure having a level decreasing in the X-direction and the second step structure may be disposed to be spaced apart from the first region R1 in a relatively great distance and may be a staircase structure having a level increasing in the X-direction. For example, in each gate pad region GP, a slope of the first step structure may be smaller than a slope of the second step structure in the first region R1. However, in some implementations, the first and second step structures have symmetrical shapes. In the first step structure, the gate electrodes 130 may be connected to the contact plugs 170, and in the second step structure, the gate electrodes 130 may form a dummy region or dummy structure not connected to the contact plugs 170. In some implementations, the specific shape of the step structure, and the number of gate electrodes 130 included in each step structure are not limited to the example illustrated in FIG. 2A. In some implementations, the gate electrodes 130 are disposed to have a step structure even in the Y-direction.

As illustrated in FIG. 3A, by the first step structure, in the gate electrodes 130, the lower gate electrode 130 may extend further than the upper gate electrode 130, and each may have contact regions 130P exposed upwardly from the interlayer insulating layers 120. The gate electrodes 130 may be connected to the contact plugs 170 in the contact regions 130P, which are end regions. Gate electrodes 130 other than the first upper gate electrode 130U1 may have an increased thickness in the contact regions 130P. The gate electrodes 130 may have a thickness T2 greater in the contact region 130P than a thickness T1 in a region including the first region R1 in which other gate electrodes 130 are disposed on the upper surface.

The gate electrodes 130 may include a metal material, such as tungsten (W). In some implementations, the gate electrodes 130 may include polycrystalline silicon or a metal silicide material. In some implementations, the gate electrodes 130 may further include a diffusion barrier, and for example, the diffusion barrier may include tungsten nitride (WN), tantalum nitride (TaN), titanium nitride (TiN), or a combination thereof.

The interlayer insulating layers 120 may be disposed between the gate electrodes 130. Similarly to the gate electrodes 130, the interlayer insulating layers 120 may be spaced apart from each other in a direction perpendicular to an upper surface of the plate layer 101 and may extend in the X-direction. The interlayer insulating layers 120 may include an insulating material such as silicon oxide or silicon nitride. In some implementations, the thickness of each of the interlayer insulating layers 120 may be varied.

The first channel structures CH may extend in the Z-direction through the gate electrodes 130 other than the first upper gate electrode 130U1, and may be connected to the plate layer 101. The first channel structures CH may form a memory cell string together with the second channel structures SCH, and may be spaced apart from each other while forming rows and columns on the plate layer 101 in the first region R1. The first channel structures CH may be disposed to form a lattice pattern on the X-Y plane or may be disposed in a zigzag pattern in one direction. The first channel structures CH may have a columnar shape and may have an inclined side surface having a width decreasing toward the plate layer 101. Among the first channel structures CH, at least a portion including the first channel structures CH disposed on an end of the first region R1 may be dummy channel structures.

The first channel structures CH may include lower and upper channel structures CH1 and CH2 which may be vertically stacked. The first channel structures CH may have a form in which the lower channel structures CH1 and the upper channel structures CH2 are connected to each other, and may have a bent portion due to a difference in width in the connection region. However, in some implementations, the number of channel structures stacked in the Z-direction is varied.

Each of the first channel structures CH may include a first channel layer 140, a first gate dielectric layer 145, a first channel buried insulating layer 147, and a first channel pad 149 disposed in a lower channel hole. As illustrated in the enlarged view in FIG. 3C, the first channel layer 140 are formed in an annular shape surrounding the internal first channel buried insulating layer 147, but in some implementations, the first channel layer 140 has a column shape such as a cylinder or a prismatic column without the first channel buried insulating layer 147. The first channel layer 140 may be connected to the first horizontal conductive layer 102 in a lower portion. The first channel layer 140 may include a semiconductor material such as polycrystalline silicon or single crystalline silicon.

The first gate dielectric layer 145 may be disposed between the gate electrodes 130 and the first channel layer 140. Although not specifically illustrated, the first gate dielectric layer 145 may include a tunneling layer, a charge storage layer, and a blocking layer stacked in order from the first channel layer 140. The tunneling layer may tunnel electric charges into the charge storage layer, and may include, for example, silicon oxide (SiO₂), silicon nitride (Si₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), a high-k dielectric material, or a combination thereof. In some implementations, at least a portion of the gate dielectric layer 145 extends in a horizontal direction along the gate electrodes 130.

The first channel pad 149 may be disposed only on an upper end of the upper channel structure CH2. The first channel pad 149 may include, for example, doped polycrystalline silicon.

The first channel layer 140, the first gate dielectric layer 145, and the first channel buried insulating layer 147 may be connected to each other between the lower channel structure CH1 and the upper channel structure CH2. A region in which the lower channel structure CH1 and the upper channel structure CH2 are connected to each other may be a region in which the interlayer insulating layers 120 are disposed.

The second channel structures SCH may penetrate through the first upper gate electrode 130U1, may extend in the Z-direction, and may be connected to the first channel structures CH, respectively. The second channel structures SCH may be disposed on the first channel structures CH, respectively, and may be horizontally shifted from the first channel structures CH, but is not limited thereto.

As illustrated in FIG. 3B, each of the second channel structures SCH includes a second channel layer 160, a second gate dielectric layer 165, a second channel buried insulating layer 167, and a second channel pad 169 disposed in an upper channel hole. The second channel layer 160 may be formed in an annular shape surrounding the second channel buried insulating layer 167 therein. The second channel layer 160 may be connected to the connection pad 151 in a lower portion and may be electrically connected to the first channel layer 140 of the first channel structure CH through the connection pad 151.

The description of the materials of each of the first channel layer 140, the first gate dielectric layer 145, the first channel buried insulating layer 147, and the first channel pad 149 described above may be respectively applied to the materials of the second channel layer 160, the second gate dielectric layer 165, the second channel buried insulating layer 167, and the second channel pad 169.

The horizontal insulating layer 150 may be disposed between the first channel structures CH and the second channel structures SCH and may extend horizontally in the first region R1 and the second region R2. The horizontal insulating layer 150 may be disposed between the first upper gate electrode 130U1 and the second upper gate electrode 130U2. The horizontal insulating layer 150 may be used as an etch stop layer when forming the second channel structures SCH and may also be used when forming the connection pads 151.

The horizontal insulating layer 150 may include an insulating material and may include a material different from that of the second and third cell region insulating layers 194 and 196. The horizontal insulating layer 150 may be a hydrogen blocking layer and may include a material blocking or reducing diffusion of hydrogen (H). The horizontal insulating layer 150 may include nitride, and may include, for example, at least one of SiN, SiON, SiCN, and SiOCN.

The connection pads 151 may penetrate through the horizontal insulating layer 150 between the first channel structures CH and the second channel structures SCH and may electrically connect the first channel layers 140 to the second channel layers 160. The connection pads 151 may be formed by partially removing the horizontal insulating layer 150 and may have upper surfaces coplanar with an upper surface of the horizontal insulating layer 150. The connection pads 151 may be disposed be partially recessed into the first channel pads 149. However, the specific arrangement form of the connection pads 151 may be varied in some implementations. The connection pads 151 may include a conductive material, such as polycrystalline silicon.

The first isolation regions MS may penetrate through at least a portion of the gate electrodes 130 and may extend in the X-direction. The first isolation regions MS may be disposed to penetrate through the gate electrodes 130 other than the first upper gate electrode 130U1. As illustrated in FIG. 1A, the first isolation regions MS may be disposed parallel to each other. As illustrated in FIG. 2B, the first isolation regions MS may penetrate through the gate electrodes 130 stacked on the plate layer 101, may further penetrate through the first and second horizontal conductive layers 102 and 104 there below and may be connected to the plate layer 101. A portion of the isolation regions MS may extend as an integrated region along the first region R1 and the second region R2, and the other portion may extend only to a portion of the second region R2, or may be intermittently disposed in the first region R1 and the second region R2. However, in some implementations, the arrangement type and the number of the first isolation regions MS are not limited to the examples illustrated in FIG. 1A.

A gate isolation insulating layer 105 may be disposed in each of the first isolation regions MS. The gate isolation insulating layer 105 may have a shape of which a width may decrease toward the plate layer 101 due to a high aspect ratio. The gate isolation insulating layer 105 may include an insulating material, for example, silicon oxide, silicon nitride, or silicon oxynitride.

The second isolation regions US may extend in the X-direction between first isolation regions MS adjacent to each other, as illustrated in FIG. 1A. The second isolation regions US may be disposed in a portion of the second region R2 and the first region R1. The second isolation regions US may penetrate through the first upper gate electrode 130U1 that is an uppermost gate electrode among the gate electrodes 130. The second isolation regions US may divide the first upper gate electrode 130U1 in the Y-direction, as illustrated in FIG. 2B. A portion of the second isolation regions US may be disposed on the first isolation regions MS.

Each of the second isolation regions US may include an upper isolation insulating layer 103. The upper isolation insulating layer 103 may include an insulating material, for example, silicon oxide, silicon nitride, or silicon oxynitride.

The contact plugs 170 may be connected to the contact regions 130P of the gate electrodes 130 in the gate pad regions GP of the second region R2. The contact plugs 170 may penetrate through at least a portion of the first to third cell region insulating layers 192, 194, and 196 and may be connected to the contact regions 130P of the gate electrodes 130 exposed upwardly, respectively. The contact plugs 170 may penetrate through the gate electrodes 130 below the contact regions 130P, may penetrate through the second horizontal conductive layer 104, the horizontal sacrificial layer 110, and the plate layer 101 and may be connected to the circuit interconnection lines 280 in the peripheral circuit region PERI. The contact plugs 170 may be spaced apart from the gate electrodes 130 below the contact regions 130P by the contact insulating layers 125. The contact plugs 170 may be spaced apart from the plate layer 101, the horizontal sacrificial layer 110, and the second horizontal conductive layer 104 by the substrate insulating layers 121. However, in some implementations, the contact plugs 170 are disposed to not penetrate through the gate electrodes 130, and in this case, the contact plugs 170 may be connected to each of the contact regions 130P of the gate electrodes 130 exposed upwardly.

The contact plugs 170 may have a shape corresponding to that of the channel structures CH. Each of the contact plugs 170 may include a lower region and an upper region penetrating through the first and second stack structures GS1 and GS2, respectively. As illustrated in FIG. 3A, the upper region has a bent portion BE of which a width may discontinuously change below the horizontal insulating layer 150. The level of the bent portion BE may correspond to a level of the lower ends of the dummy vertical structures 180. The lower region may further penetrate through the substrate insulating layer 121. The lower region and the upper region may have a cylindrical shape of which a width may decrease toward the substrate 201 due to an aspect ratio. Each of the contact plugs 170 may further include a landing region of which a width may be extended below the substrate insulating layer 121. However, in some implementations, the contact plugs 170 do not include the landing region.

As illustrated in FIG. 3A, each of the contact plugs 170 has a horizontally extended form in the contact region 130P. The contact plug 170 may include a vertical extension portion 170V extending in the Z-direction and a horizontal extension portion 170H extending horizontally from the vertical extension portion 170V and in contact with the gate electrode 130. The horizontal extension portion 170H may be disposed along a circumference of the vertical extension portion 170V, and the entire side surface may be surrounded by the gate electrode 130. A length from a side surface of the vertical extension portion 170V to an end of the horizontal extension portion 170H may be smaller than a length from a side surface of the vertical extension portion 170V to external side surfaces of the contact insulating layers 125. The contact plugs 170 may be spaced apart from the gate electrodes 130 below the contact regions 130P, that is, the gate electrodes 130 not electrically connected, by the contact insulating layers 125.

The contact plugs 170 may include at least one of a conductive material, for example, tungsten (W), copper (Cu), aluminum (Al), and an alloy thereof. In some implementations, the contact plugs 170 include a barrier layer extending along a side surface and a bottom surface, or may have an air gap therein.

The contact insulating layers 125 may be disposed to surround side surfaces of each of the contact plugs 170 below the contact regions 130P. The contact insulating layers 125 may be disposed spaced apart from each other in the Z-direction around each of the contact plugs 170. The contact insulating layers 125 may be disposed on substantially the same level as a level of the gate electrodes 130. The contact insulating layers 125 may include an insulating material, for example, silicon oxide, silicon nitride, or silicon oxynitride.

The upper contact plug 172 may be connected to the first upper gate electrode 130U1. Differently from the contact plugs 170, the upper contact plug 172 may not penetrate through the first upper gate electrode 130U1. The upper contact plug 172 may be disposed to be partially recessed into the first upper gate electrode 130U1 from the upper surface or may be disposed to contact to the upper surface. The upper contact plug 172 may include a conductive material, and may include the same material as that of the contact plugs 170, but implementations are not limited thereto.

The dummy vertical structures 180 may be disposed around the contact plugs 170. As illustrated in FIGS. 1A and 1B, the dummy vertical structures 180 may be disposed in the second region R2 in a circular shape on a plan view, and may be disposed around the contact plugs 170 in a regular form. For example, four dummy vertical structures 180 may be disposed around the contact plug 170, but implementations are not limited thereto. The dummy vertical structures 180 may be regularly and continuously disposed even in regions in which the contact plugs 170 are spaced apart from each other in the X-direction. In some implementations, the dummy vertical structures 180 are further disposed on the first isolation regions MS1. The dummy vertical structures 180 are not limited to circular shapes on a plan view, and may have various shapes such as a polygonal shape and an oval shape. As illustrated in FIG. 3A, a diameter D2 of the dummy vertical structures 180 is equal to or smaller than a diameter D1 of the contact plugs 170.

The dummy vertical structures 180 may be disposed on the gate electrodes 130 other than the first upper gate electrode 130U1 and the first isolation regions MS1, on an external side of the first upper gate electrode 130U1. Accordingly, the arrangement form of the dummy vertical structures 180 on the plan view may be varied within the range of being spaced apart from the contact plugs 170, regardless of the arrangement of the gate electrodes 130 and the first isolation regions MS1.

The dummy vertical structures 180 may be disposed to penetrate through the horizontal insulating layer 150, as illustrated in FIGS. 2A and 3A. Upper ends of the dummy vertical structures 180 may be disposed on substantially the same level as a level of the upper ends of the contact plugs 170. The upper ends of the dummy vertical structures 180 may be disposed on a level higher than a level of the upper surface of the first upper gate electrode 130U1. The dummy vertical structures 180 may have a second length L2 smaller than a first length L1 of the contact plugs 170 in the Z-direction. The lower ends of the dummy vertical structures 180 may be disposed on a level higher than a level of the lower ends of the contact plugs 170. The lower ends of the dummy vertical structures 180 may be disposed on a level equal to or lower than a level of the level of the lower surface of the horizontal insulating layer 150, and may be disposed on a level higher than a level of the upper surface of the second upper gate electrode 130U2. The lower ends of the dummy vertical structures 180 may be disposed on a level lower than a level of the lower ends of the second channel structures SCH. The lower ends of the dummy vertical structures 180 may be disposed on a level higher than a level of an uppermost surface of the memory gate electrodes 130M. The dummy vertical structures 180 may overlap the first upper gate electrode 130U1 in the horizontal direction.

Upper surfaces of the dummy vertical structures 180 may be entirely covered with the third cell region insulating layer 196. The entire surface of the dummy vertical structures 180 may be covered with an insulating material. The dummy vertical structures 180 may be disposed to not be connected to a conductive structure and may not perform an electrical function in the semiconductor device 100.

The dummy vertical structures 180 may include a conductive material, for example, at least one of tungsten (W), copper (Cu), aluminum (Al), and an alloy thereof. The dummy vertical structures 180 may be formed through the same deposition process as a deposition process for the contact plugs 170 and may include the same material as the contact plugs 170, for example, a metal material. For example, when contact plugs 170 include a barrier layer, the dummy vertical structures 180 may also include a barrier layer. However, in some implementations, the dummy vertical structures 180 may be formed through a deposition process different from a deposition process for the contact plugs 170, and in this case, the dummy vertical structures 180 may be formed of an insulating material.

In some implementations, the dummy vertical structures 180 are disposed to penetrate through the horizontal insulating layer 150, such that a movement path of hydrogen (H) may be formed from above the horizontal insulating layer 150 to below the horizontal insulating layer 150 during the process of manufacturing the semiconductor device 100. Accordingly, hydrogen passivation may be performed on the lower structure including the first channel structures CH, such that defects such as a dangling bond and a trap may be addressed, and reliability and electrical properties of the semiconductor device 100 may be improved.

The studs 185 may be included in a cell interconnection structure electrically connected to memory cells in a memory cell region CELL. The studs 185 may be connected to the second channel structures SCH and the contact plugs 170, and may be electrically connected to the first and second channel structures CH, SCH and the gate electrodes 130. The studs 185 may not be disposed on the dummy vertical structures 180. The studs 185 may have a plug shape in the illustrated example, but implementations are not limited thereto, and the studs 185 may have a line shape. In some implementations, the number of plugs and interconnection lines included in the cell interconnection structure are varied. The studs 185 may include metal, for example, tungsten (W), copper (Cu), or aluminum (Al).

The first to third cell region insulating layers 192, 194, and 196 may be disposed to cover the first and second stack structures GS1 and GS2. The first cell region insulating layer 192 may cover the first stack structure GS1, the second cell region insulating layer 194 may cover a portion of the second stack structure GS2 disposed below the horizontal insulating layer 150, and the third cell region insulating layer 196 may be disposed on the horizontal insulating layer 150 and may cover a side surface of the first upper gate electrode 130U1. The first to third cell region insulating layers 192, 194, and 196 may be formed of an insulating material or may include a plurality of insulating layers. When the first to third cell region insulating layers 192, 194, and 196 include the same material as that of the interlayer insulating layers 120, an interfacial surface with the interlayer insulating layers 120 may not be distinct.

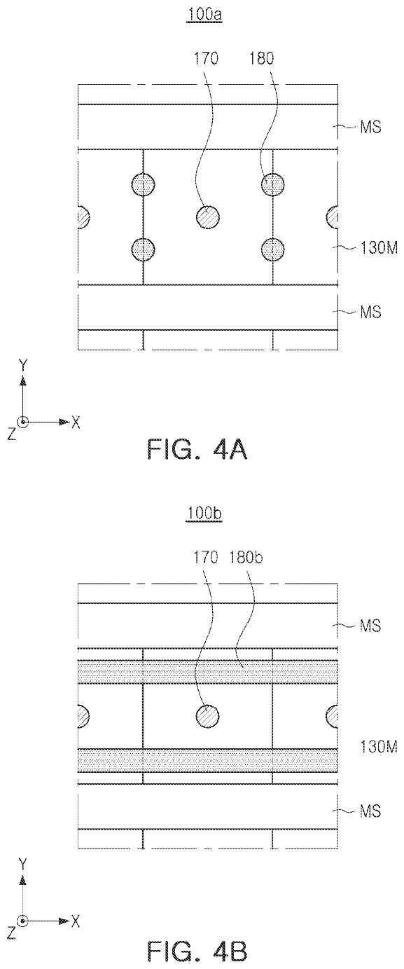

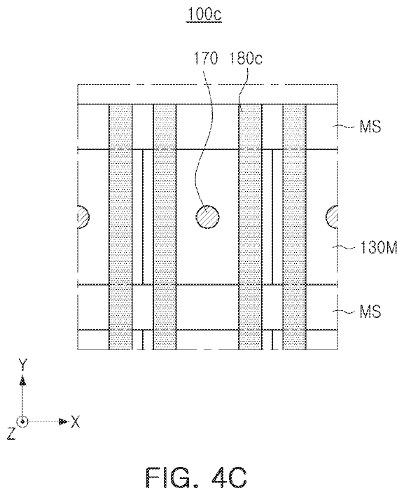

FIGS. 4A to 4C are enlarged views illustrating a portion of another example of a semiconductor device, illustrating a plane corresponding to FIG. 1B.

Referring to FIG. 4A, in a semiconductor device 100a, the arrangement form of the dummy vertical structures 180 is different from the example implementation in FIG. 1B. The dummy vertical structures 180 is disposed on ends of gate electrodes 130 in a plan view. In some implementations, the dummy vertical structures 180 may be disposed in the same form on the first isolation regions MS1.

Referring to FIG. 4B, in the semiconductor device 100b, the dummy vertical structures 180b have a line shape extending in the X-direction. However, the length in the X-direction of the dummy vertical structures 180b may be varied in in some implementations. In some implementations, the dummy vertical structures 180b may be further disposed on the first isolation regions MS1.

Referring to FIG. 4C, in the semiconductor device 100c, the dummy vertical structures 180c have a line shape extending in the Y-direction. The dummy vertical structures 180c may also be extended to a region above the first isolation regions MS1. However, the length in the Y-direction of dummy vertical structures 180c may be varied in some implementations.

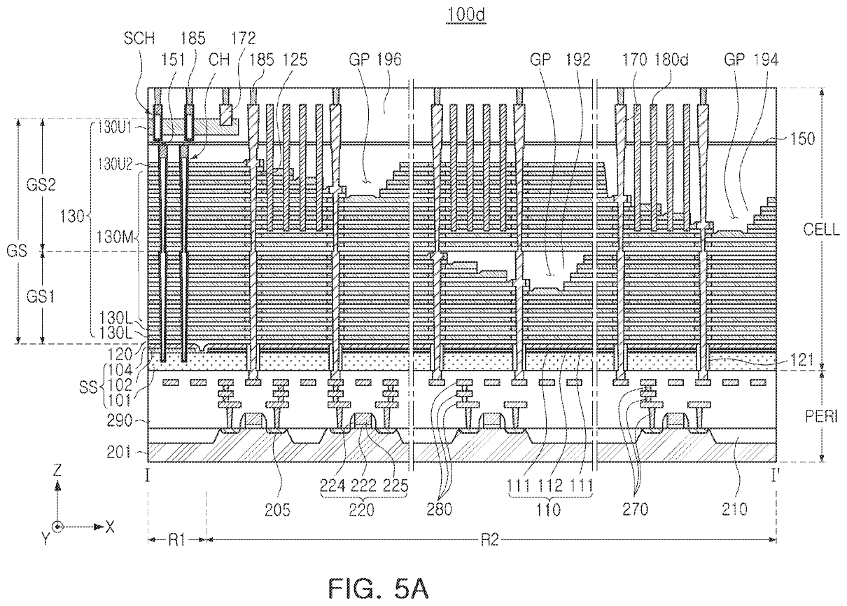

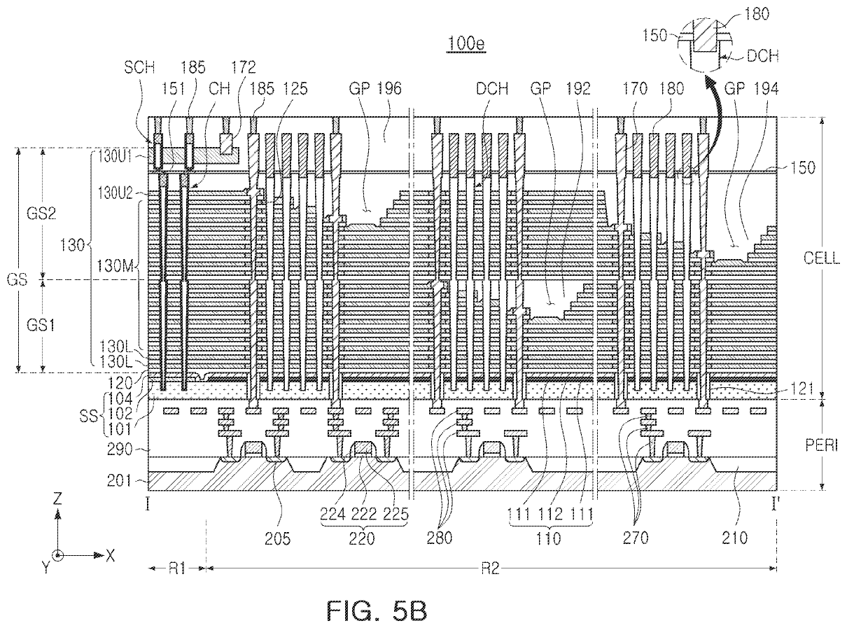

FIGS. 5A and 5B are cross-sectional views illustrating another example of a semiconductor device, illustrating cross-sections corresponding to FIG. 2A.

Referring to FIG. 5A, in a semiconductor device 100d, dummy vertical structures 180d have a relatively long length.

The dummy vertical structures 180d may penetrate through a portion of the gate electrodes 130 and may extend downwardly. For example, the dummy vertical structures 180d may penetrate through a portion of the gate electrodes 130 included in the second stack structure GS2 and may extend downwardly. However, in some implementations, the number of the gate electrodes 130 penetrating through the dummy vertical structures 180d may be varied. Even in this case, the length of the dummy vertical structures 180d may be smaller than the length of the contact plugs 170. The diameter of the dummy vertical structures 180d may be smaller than the diameter of the contact plugs 170, but an example implementation thereof is not limited thereto.

In some implementations, the dummy vertical structures 180d are connected to the plurality of gate electrodes 130 such that the dummy vertical structures 180d may be formed of an insulating material. In some implementations, the dummy vertical structures 180d are disposed to penetrate through or to be recessed into only the second upper gate electrode 130U2. In this case, the dummy vertical structures 180d may include a conductive material or an insulating material.

Referring to FIG. 5B, in the semiconductor device 100e, the memory cell region CELL further includes a support structure DCH.

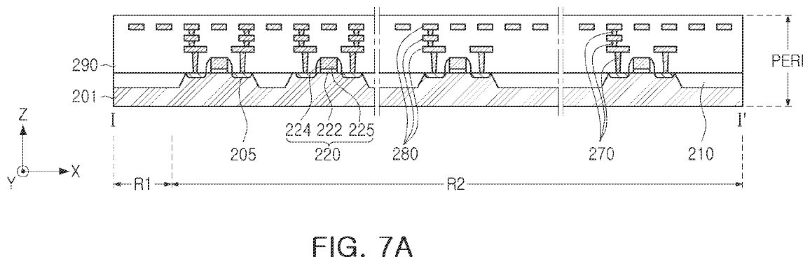

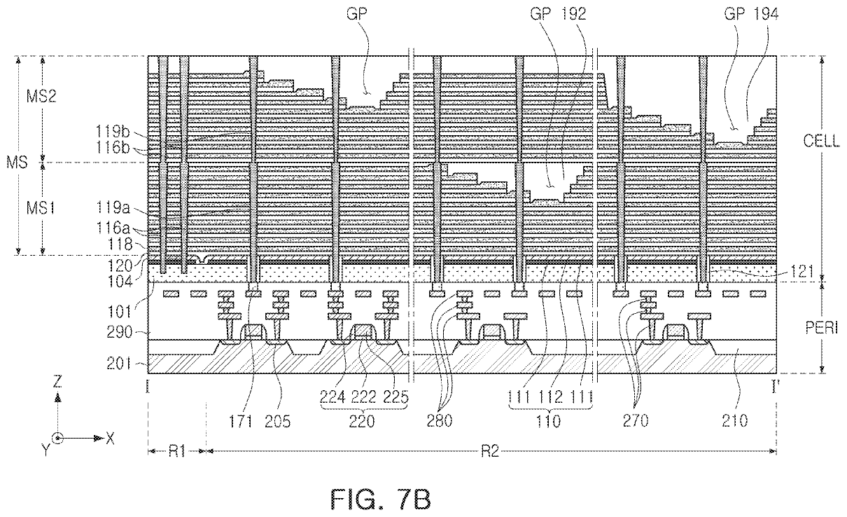

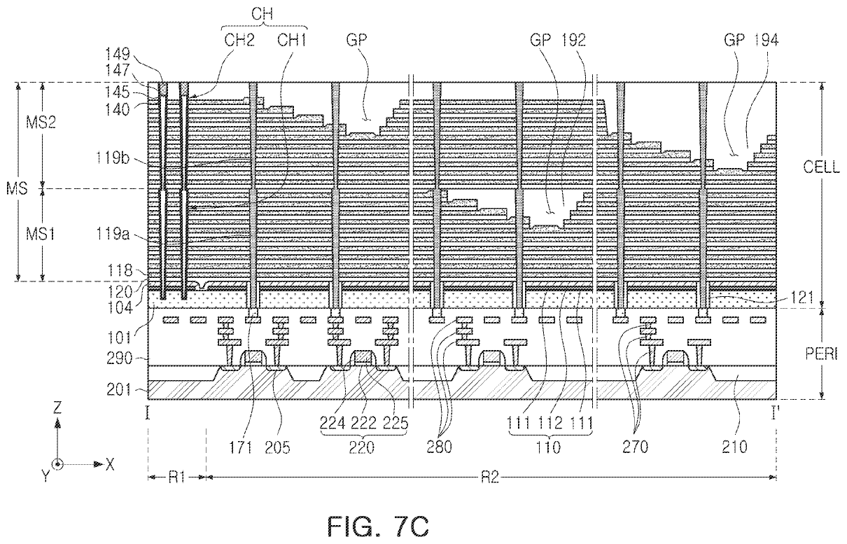

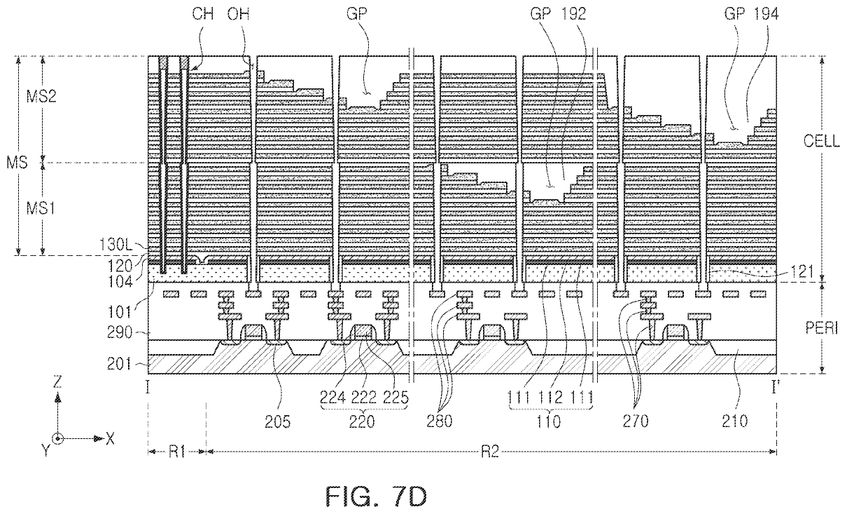

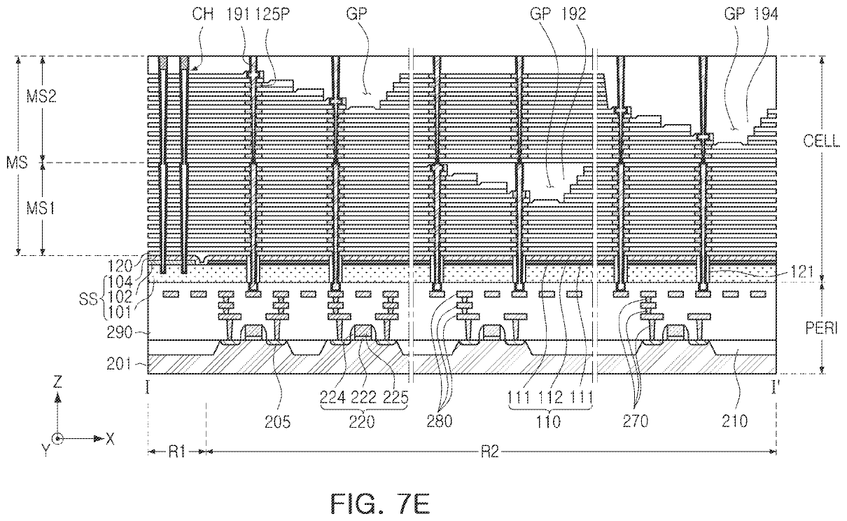

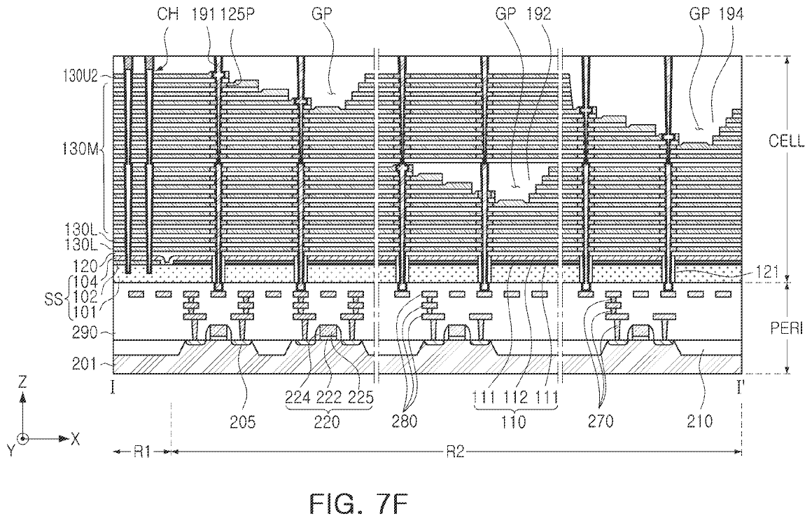

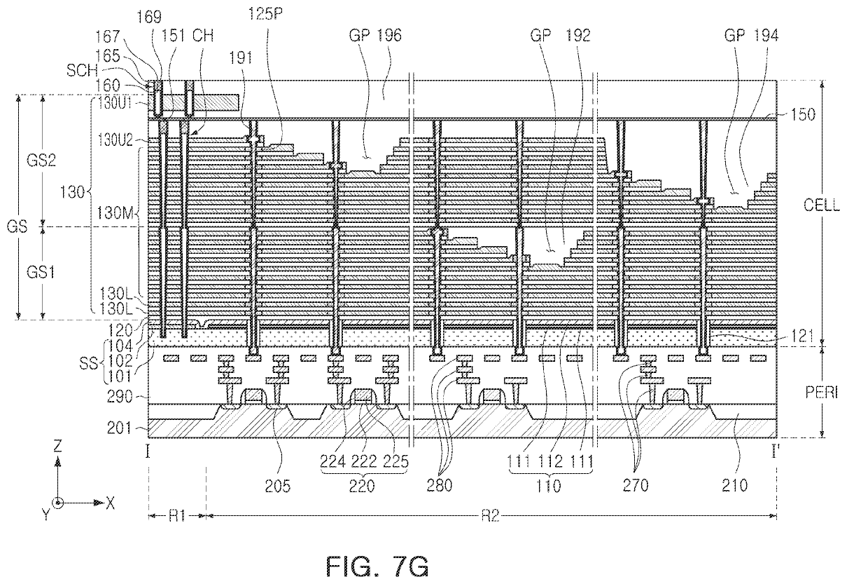

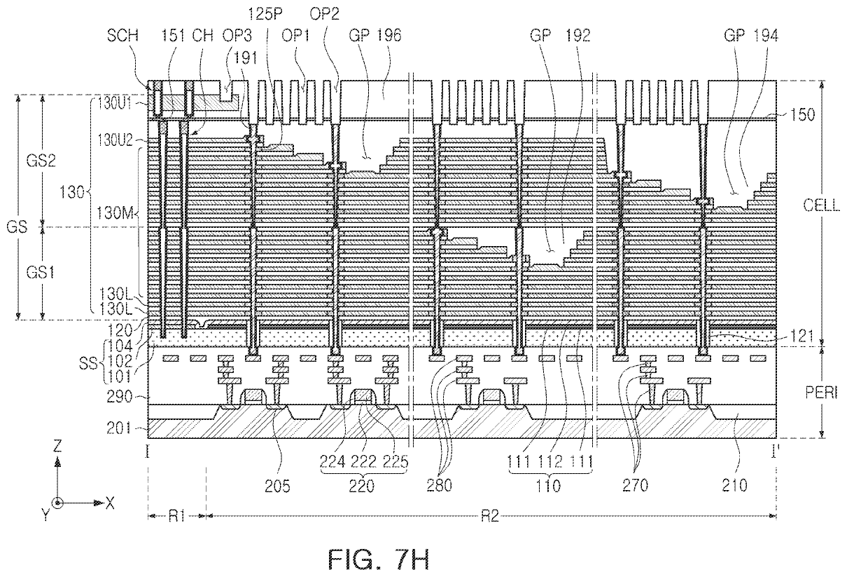

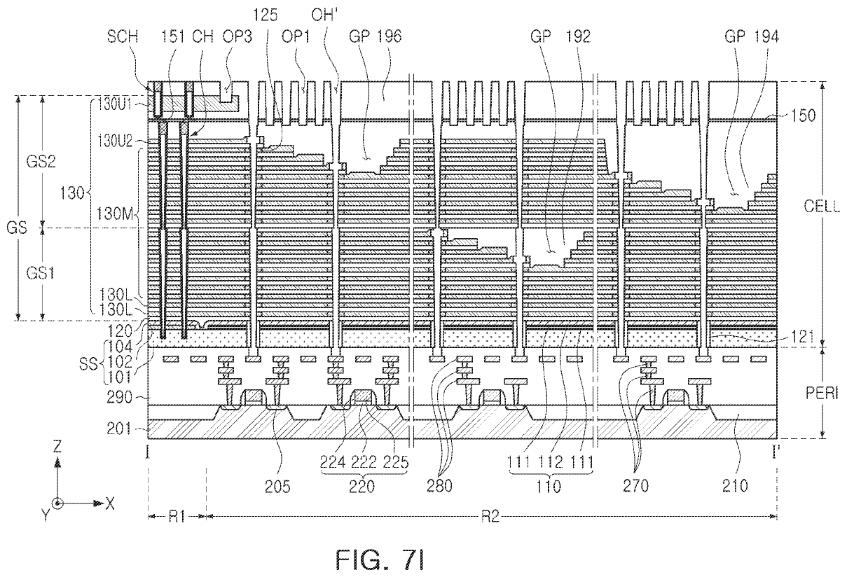

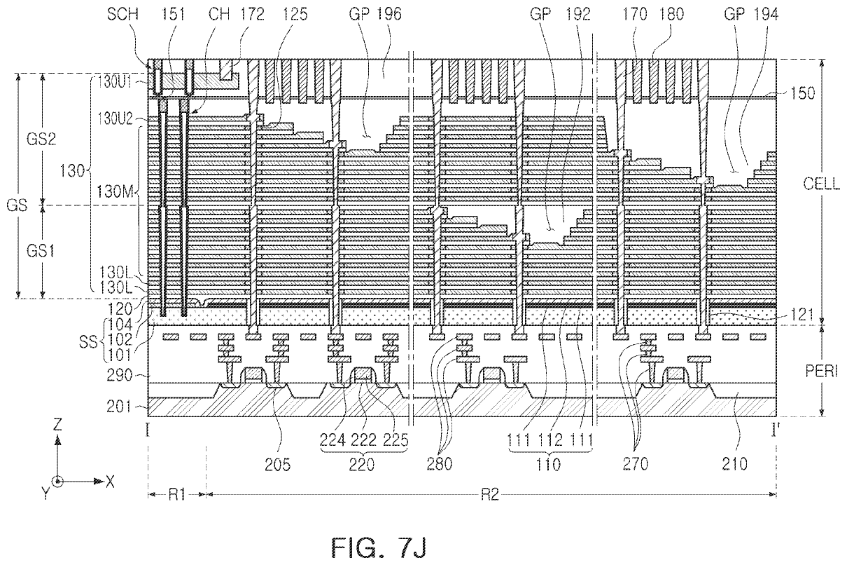

The support structure DCH may be disposed below the horizontal insulating layer 150 and may be configured to support the mold structure MS (see FIG. 7E) including the interlayer insulating layers 120 during the process of manufacturing the semiconductor device 100e. The upper ends of the support structure DCH may be disposed on substantially the same level as a level of the upper ends of the first channel structures CH.

In some implementations, at least a portion of the support structure DCH may be disposed to overlap the dummy vertical structures 180 in the Z-direction. In this case, as illustrated in the enlarged view in FIG. 5B, the dummy vertical structures 180 may be disposed to be partially recessed into an upper portion of the support structure DCH. In some implementations, the relative sizes of the dummy vertical structures 180 and the support structure DCH are varied. In some implementations, the support structure DCH does not overlap the dummy vertical structures 180 in the Z-direction.

The support structure DCH may include an insulating material, and may include, for example, silicon oxide, silicon nitride, silicon carbide, or silicon oxynitride.

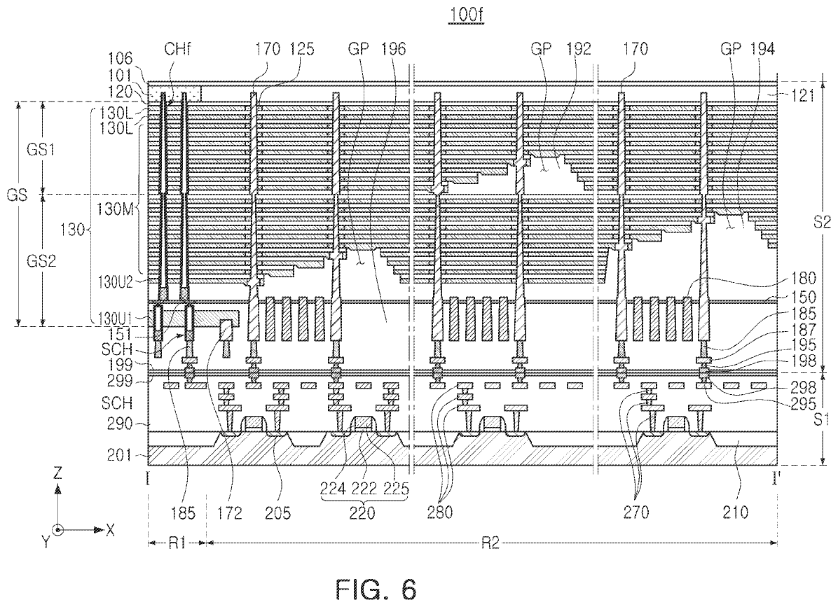

FIG. 6 is a cross-sectional view illustrating another example of a semiconductor device.

Referring to FIG. 6, a semiconductor device 100f includes a first semiconductor structure S1 and a second semiconductor structure S2 bonded to each other by a wafer bonding method.

The description of the peripheral circuit region PERI described above with reference to FIGS. 1A to 2B may be applied to the first semiconductor structure S1. However, the first semiconductor structure S1 may further include first bonding vias 295, first bonding metal layers 298, and first bonding insulating layer 299, which are bonding structures. The first bonding vias 295 may be disposed above the uppermost circuit interconnection lines 280 and may be connected to the circuit interconnection lines 280. At least a portion of the first bonding metal layers 298 may be connected to the first bonding vias 295 on the first bonding vias 295. The first bonding metal layers 298 may be connected to the second bonding metal layers 198 of the second semiconductor structure S2. The bonding metal layers 298 may provide, together with the second bonding metal layers 198, an electrical connection path according to bonding between the first semiconductor structure S1 and the second semiconductor structure S2. A portion of the first bonding metal layers 298 may be disposed only for bonding without being connected to the lower circuit interconnection lines 280. The first bonding vias 295 and the first bonding metal layers 298 may include a conductive material such as copper (Cu). A first bonding insulating layer 299 may be disposed around the first bonding metal layers 298. The first bonding insulating layer 299 may also function as a diffusion barrier of the first bonding metal layers 298, and may include, for example, at least one of SiN, SiON, SiCN, SiOC, SiOCN, and SiO.

As for the second semiconductor structure S2, unless otherwise indicated, the description of the memory cell region CELL described above with reference to FIGS. 1A to 3C may be applied. The second semiconductor structure S2 may further include cell interconnection lines 187, which is a cell interconnection structure, and may further include second bonding vias 195, second bonding metal layers 198, and second bonding insulating layer 199, which are bonding structures. The second semiconductor structure S2 may further include a passivation layer 106 covering an upper surface of the plate layer 101.

The cell interconnection lines 187 may be connected to studs 185. However, in some implementations, the number of layers and the arrangement form of plugs and interconnection lines included in the cell interconnection structure are varied. The cell interconnection lines 187 may be formed of a conductive material, and may include, for example, at least one of tungsten (W), aluminum (Al), and copper (Cu).

The second bonding vias 195 and the second bonding metal layers 198 may be disposed below the cell interconnection lines 187. The second bonding vias 195 may connect the cell interconnection lines 187 to the second bonding metal layers 198, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material such as copper (Cu). The second bonding insulating layer 199 may include, for example, at least one of SiO, SiN, SiCN, SiOC, SiON, and SiOCN.

The first and second semiconductor structures S1 and S2 may be bonded to each other by bonding between the first bonding metal layers 298 and the second bonding metal layers 198 and bonding between the first bonding insulating layer 299 and the second bonding insulating layer 199. The bonding between the first bonding metal layers 298 and the second bonding metal layers 198 may be, for example, copper (Cu)-to-copper (Cu) bonding, and the bonding between the first bonding insulating layer 299 and the second bonding insulating layer 199 may be, for example, dielectric-to-dielectric bonding such as SiCN-to-SiCN bonding. The first and second semiconductor structures S1 and S2 may be bonded to each other by hybrid bonding including copper (Cu)-to-copper (Cu) bonding and dielectric-to-dielectric bonding.

The passivation layer 106 may be disposed on an upper surface of the plate layer 101 and may protect the semiconductor device 100f. The passivation layer 106 may include an insulating material such as at least one of silicon oxide, silicon nitride, and silicon carbide. The substrate insulating layer 121 may be relatively widely disposed in the second region R2 to cover upper ends of the contact plugs 170. However, in some implementations, the arrangement form of the substrate insulating layer 121 are varied within the range of electrically isolating the contact plugs 170 from the plate layer 101.

In some implementations, the second semiconductor structure S2 does not include the first and second horizontal conductive layers 102 and 104 (see FIG. 2A). The first channel structures CHf may be directly connected to the plate layer 101 through an upper end while the first channel layers 140 (see FIG. 3C) is exposed. However, the form of electrical connection between the first channel structures CHf and the common source line may be varied in some implementations, and the first channel structures and the source structure may have the same structure as the example implementation in FIG. 2A.

FIGS. 7A to 7J are cross-sectional views illustrating an example of a method of manufacturing a semiconductor device, illustrating a region corresponding to FIG. 2A.

Referring to FIG. 7A, circuit devices 220, a circuit interconnection structure, and a peripheral region insulating layer 290 included in a peripheral circuit region PERI are formed on a substrate 201.

First, the device isolation layers 210 may be formed in the substrate 201, and a circuit gate dielectric layer 222 and a circuit gate electrode 225 may be formed in order on the substrate 201. The device isolation layers 210 may be formed by, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but implementations are not limited thereto. Thereafter, a spacer layer 224 and impurity regions 205 may be formed on both side walls of the circuit gate dielectric layer 222 and the circuit gate electrode 225. In some implementations, the spacer layer 224 includes a plurality of layers. The impurity regions 205 may be formed by performing an ion implantation process.

The circuit contact plugs 270 of the circuit interconnection structure may be formed by forming a portion of the peripheral region insulating layer 290, removing a portion thereof by etching, and filling a conductive material therein. The circuit interconnection lines 280 may be formed, for example, by depositing a conductive material and patterning the lines.

The peripheral region insulating layer 290 may include a plurality of insulating layers. The peripheral region insulating layer 290 may be provided as a portion in each process of forming the circuit interconnection structure. Accordingly, the peripheral circuit region PERI may be formed.

Referring to FIG. 7B, a plate layer 101 on which a memory cell region CELL is provided, a horizontal sacrificial layer 110, a second horizontal conductive layer 104, and a substrate insulating layer 121 are formed on the peripheral circuit region PERI, and a mold structure MS, first and second channel sacrificial layers 116a and 116b, and first and second contact sacrificial layers 119a and 119b are formed.

The plate layer 101 may be formed on the peripheral region insulating layer 290. The plate layer 101 may be formed of, for example, polycrystalline silicon and may be formed by a CVD process. Polycrystalline silicon included in the plate layer 101 may include impurities.

When the plate layer 101 is formed, landing pads 171 may be formed together on the uppermost circuit interconnection lines 280. The landing pads 171 may be formed in a region in which a lower end of the contact plugs 170 (see FIG. 2A) is disposed. First, before forming the plate layer 101, openings may be formed by partially removing the peripheral region insulating layer 290 on the uppermost circuit interconnection lines 280. When the plate layer 101 is formed, the landing pads 171 may be formed by filling the openings with a material included in the plate layer 101. The openings may be formed together with, for example, ground vias for connecting the plate layer 101 and the circuit interconnection structure.

The first and second horizontal sacrificial layers 111 and 112 included in the horizontal sacrificial layer 110 may be alternately stacked on the plate layer 101. A portion of the horizontal sacrificial layer 110 may be replaced with the first horizontal conductive layer 102 in FIG. 2B through a subsequent process. The first horizontal sacrificial layers 111 may include a material different from that of the second horizontal sacrificial layer 112. For example, the first horizontal sacrificial layers 111 may be formed of the same material as that of the interlayer insulating layers 120, and the second horizontal sacrificial layer 112 may be formed of the same material as that of the subsequent sacrificial insulating layers 118. A portion of the horizontal sacrificial layer 110 may be removed by a patterning process in partial regions, for example, the second region R2.

The second horizontal conductive layer 104 may be formed on the horizontal sacrificial layer 110 and may be in contact with the plate layer 101 from a region in which the horizontal sacrificial layer 110 is removed.

The substrate insulating layer 121 may be formed to penetrate through the plate layer 101 in partial regions including a region in which contact plugs 170 (see FIG. 2A) are to be disposed. The substrate insulating layer 121 may be formed by removing a portion of the plate layer 101, the horizontal sacrificial layer 110, and the second horizontal conductive layer 104 and filling the insulating material therein. After filing the insulating material, a planarization process may be further performed using a chemical mechanical polishing or CMP process. Accordingly, an upper surface of the substrate insulating layer 121 may be substantially coplanar with an upper surface of the second horizontal conductive layer 104.

Thereafter, a first mold structure MS1 of the mold structure MS may be formed, and the first channel sacrificial layers 116a and the first contact sacrificial layers 119a penetrating through the first mold structure MS1 may be formed.

The first mold structure MS1 may be formed on the second horizontal conductive layer 104 and the substrate insulating layer 121 on a level on which the first stack structure GS1 (see FIG. 2A) is disposed.

At least a portion of the sacrificial insulating layers 118 may be replaced with a portion of the gate electrodes 130 (see FIG. 2A) through a subsequent process. The sacrificial insulating layers 118 may be formed of a material different from that of the interlayer insulating layers 120, and may be formed of a material etched with etch selectivity under specific etching conditions with respect to the interlayer insulating layers 120. For example, the interlayer insulating layer 120 may be formed of at least one of silicon oxide and silicon nitride, and the sacrificial insulating layers 118 may be formed of a material different from that of the interlayer insulating layer 120 selected from among silicon, silicon oxide, silicon carbide, and silicon nitride. The number of the interlayer insulating layers 120 and the sacrificial insulating layers 118 may be varied from the illustrated examples.

The gate pad region GP may be formed by repeatedly performing a photolithography process and an etching process for the sacrificial insulating layers 118 and the interlayer insulating layers 120. The gate pad regions GP may be formed in the second region R2, and the upper sacrificial insulating layers 118 may include a region extending shorter than the lower sacrificial insulating layers 118. In the gate pad region GP, asymmetric step structures may be formed such that upper surfaces and ends of the plurality of sacrificial insulating layers 118 may be upwardly exposed. However, in some implementations, the specific form of gate pad region GP are varied. By further forming the sacrificial insulating layers 118 on the step structure of the gate pad regions GP, the sacrificial insulating layers 118 disposed on each region may be formed to have a relatively great thickness.

Thereafter, a first cell region insulating layer 192 covering the first mold structure MS1 may be formed. The first channel sacrificial layers 116a may be formed in positions corresponding to the channel structures CH (see FIG. 2A) in the first region R1. The first contact sacrificial layers 119a may be formed in positions corresponding to the contact plugs 170 (see FIG. 2A) in the second region R2. The first channel sacrificial layers 116a and the first contact sacrificial layers 119a may be formed simultaneously.

The first channel sacrificial layers 116a and the first contact sacrificial layers 119a may be formed by forming first holes to penetrate through the first mold structure MS1, depositing a sacrificial layer material on the first holes, and performing a planarization process. The first channel sacrificial layers 116a and the first contact sacrificial layers 119a may include, for example, at least one of TiN and polycrystalline silicon.

The second mold structure MS2, the second channel sacrificial layers 116b, and the second contact sacrificial layers 119b may be formed on the first mold structure MS1 in the same manner as in the process for forming each of the first mold structure MS1, the first channel sacrificial layers 116a, and the first contact sacrificial layers 119a.

Referring to FIG. 7C, first channel structures CH penetrating through the mold structure MS are formed.

The first channel structures CH may be formed by forming lower channel holes by removing the first and second channel sacrificial layers 116a and 116b, and depositing at least a portion of the first gate dielectric layer 145, the first channel layer 140, the first channel buried insulating layer 147 and the first channel pad 149 in order in the lower channel holes.

The first gate dielectric layer 145 may be formed to have a uniform thickness using an ALD or CVD process. In this process, all or a portion of the first gate dielectric layer 145 may be formed, and a portion extending perpendicular to the plate layer 101 along the first channel structures CH may be formed in this process. The first channel layer 140 may be formed on the first gate dielectric layer 145 within the lower channel holes. The first channel buried insulating layer 147 may be formed to fill the lower channel holes and may be an insulating material. The first channel pad 149 may be formed of a conductive material, for example polycrystalline silicon.

Referring to FIG. 7D, the first contact holes OH are formed by removing the first and second contact sacrificial layers 119a and 119b.

The first contact holes OH may be formed by selectively removing the first and second contact sacrificial layers 119a and 119b and further removing the exposed landing pads 171. The circuit interconnection lines 280 may be exposed through bottom surfaces of the first contact holes OH. In some implementations, the landing pads 171 are not removed in this process and may be removed in a subsequent process.

Referring to FIG. 7E, preliminary contact insulating layers 125P and vertical sacrificial layers 191 are formed on the first contact holes OH, and the sacrificial insulating layers 118 may be removed.

First, a portion of the sacrificial insulating layers 118 exposed through the first contact holes OH may be removed. Contact tunnel portions may be formed by removing the sacrificial insulating layers 118 to a predetermined length around the first contact holes OH. The contact tunnel portions may be formed to have a relatively short length in the uppermost sacrificial insulating layers 118 and to have a relatively long length in the lower sacrificial insulating layers 118.

Specifically, first, conversely, the contact tunnel portions may be formed relatively long in the uppermost sacrificial insulating layers 118, which may be because the uppermost sacrificial insulating layers 118 may include a region having an etching rate relatively faster than the sacrificial insulating layers 118 below. Thereafter, a sacrificial layer may be formed in the first contact holes OH and the contact tunnel portions. The sacrificial layer may be formed of a material having an etching rate slower than that of the sacrificial insulating layers 118. Thereafter, a portion of the sacrificial layer and sacrificial insulating layers 118 may be removed. In this case, the sacrificial layer may remain in an uppermost portion, the sacrificial layer may be removed from a lower portion, and a portion of the sacrificial insulating layers 118 may be removed. Accordingly, finally, the contact tunnel portions may be formed to have a relatively short length in the uppermost sacrificial insulating layers 118.

The preliminary contact insulating layers 125P may be formed by depositing an insulating material in the first contact holes OH and the contact tunnel portions. The preliminary contact insulating layers 125P may be formed on the side wall of the first contact holes OH and may fill the contact tunnel portions. In the uppermost sacrificial insulating layers 118, the preliminary contact insulating layers 125P may not completely fill the contact tunnel portions.

The vertical sacrificial layers 191 may fill the first contact holes OH and the uppermost contact tunnel portions. The vertical sacrificial layers 191 may include a material different from that of the preliminary contact insulating layers 125P, and may include, for example, polycrystalline silicon.

Thereafter, openings penetrating through the sacrificial insulating layers 118 and the interlayer insulating layers 120 and extending to the plate layer 101 may be formed in positions of the first isolation regions MS (see FIGS. 1A and 2B). Thereafter, the horizontal sacrificial layer 110 may be selectively removed from the first region R1 by performing an etch-back process while forming sacrificial spacer layers in the openings, and a portion of the exposed first gate dielectric layer 145 may be removed together. After forming a first horizontal conductive layer 102 by depositing a conductive material on the region from which the horizontal sacrificial layer 110 is removed, the sacrificial spacer layers may be removed from the openings. Through this process, a first horizontal conductive layer 102 may be formed in the first region R1.

Thereafter, the sacrificial insulating layers 118 may be selectively removed with respect to the interlayer insulating layers 120, the second horizontal conductive layer 104, and the preliminary contact insulating layers 125P using, for example, wet etching.

Referring to FIG. 7F, a portion of gate electrodes 130 is formed.

The gate electrodes 130 may be formed by depositing a conductive material in regions from which the sacrificial insulating layers 118 are removed. The conductive material may include a metal, polycrystalline silicon or metal silicide material. In some implementations, a portion of the first gate dielectric layer 145 is preferentially formed before forming the gate electrodes 130.

After forming the gate electrodes 130, gate isolation insulating layers 105 (see FIG. 2B) may be formed in the openings formed to correspond to the first isolation regions MS.

Referring to FIG. 7G, a horizontal insulating layer 150 and a first upper gate electrode 130U1 are formed, and second channel structures SCH penetrating through the first upper gate electrode 130U1 are formed.

The horizontal insulating layer 150 may be formed on the first channel structures CH. Thereafter, a third cell region insulating layer 196 may be partially formed and the first upper gate electrode 130U1 may be patterned. The first upper gate electrode 130U1 may include a different material from the other gate electrodes 130, but implementations are not limited thereto. For example, the first upper gate electrode 130U1 may include polycrystalline silicon. Thereafter, a third cell region insulating layer 196 may be further formed.

To form the second channel structures SCH, first, upper channel holes penetrating through the first upper gate electrode 130U1 may be formed, and second channel dielectric layers 165 and sacrificial layers may be formed in order. Thereafter, lower holes penetrating through the second channel dielectric layers 165 and the sacrificial layers and extending from bottom surfaces of the upper channel holes to the horizontal insulating layer 150 may be formed, and the first channel pads 149 may be exposed by partially removing the horizontal insulating layer 150 exposed through the lower holes. The connection pads 151 may be formed in regions from which the horizontal insulating layer 150 is removed, the sacrificial layers may be removed, and the second channel layer 160, the second channel filling layer 167, and the second channel pad 169 may be formed in order in each of the upper channel holes, thereby forming the second channel structures SCH. Each layer may be formed in the same manner as in the first channel structures CH. The second channel layers 160 may be connected to the connection pads 151 on a lower end.

Referring to FIG. 7H, first to third openings OP1, OP2, and OP3 are formed.

The first to third openings OP1, OP2, and OP3 may be formed to penetrate at least a portion of the third cell region insulating layer 196. The first openings OP1 may be formed to penetrate through the third cell region insulating layer 196 and the horizontal insulating layer 150 in a position corresponding to the dummy vertical structures 180 in FIG. 2A. The second openings OP2 may be formed to penetrate through the third cell region insulating layer 196 and the horizontal insulating layer 150 such that the preliminary contact insulating layers 125P and the vertical sacrificial layers 191 may be exposed. The third opening OP3 may be formed such that the first upper gate electrode 130U1 may be exposed. The first and second openings OP1 and OP2 may be formed simultaneously, and the third opening OP3 may be formed simultaneously with the first and second openings OP1 and OP2 or may be formed in a separate process. In some implementations, the third opening OP3 is formed in a subsequent process.

Referring to FIG. 7I, the second contact holes OH′ are formed by removing the vertical sacrificial layers 191 exposed through the second openings OP2 and partially removing the preliminary contact insulating layers 125P.

The vertical sacrificial layers 191 may be selectively removed with respect to the interlayer insulating layers 120 and the gate electrodes 130. After the vertical sacrificial layers 191 are removed, a portion of the exposed preliminary contact insulating layers 125P may also be removed. In this case, the entirety of the preliminary contact insulating layers 125P may be removed from the uppermost gate electrodes 130 corresponding to the contact regions 130P (see FIG. 3A), and may remain there below and may form the contact insulating layers 125. In the contact regions 130P, when the first gate dielectric layer 145 is exposed after the preliminary contact insulating layers 125P are removed, the first gate dielectric layer 145 may also be removed such that a side surface of the gate electrodes 130 may be exposed.

Referring to FIG. 7J, the contact plugs 170, the dummy vertical structures 180, and the upper contact plug 172 are formed.

The contact plugs 170, the dummy vertical structures 180, and the upper contact plug 172 may be formed by depositing a conductive material in the second contact holes OH′ and the first and third openings OP1 and OP3. The contact plugs 170 may be formed to have horizontal extension portions 170H (see FIG. 3A) extending horizontally from the contact regions 130P, thereby being physically and electrically connected to the gate electrodes 130. The dummy vertical structures 180 may be spaced apart from the gate electrodes 130 and may form an electrically floating state. The contact plugs 170 and dummy vertical structures 180 may be formed together and may include the same material. The upper contact plug 172 may be deposited together with the contact plugs 170 and the dummy vertical structures 180, or may be deposited in a separate process.

Thereafter, referring to FIG. 2A together, by forming contact plugs 170 and studs 185 connected to the upper ends of the second channel structures SCH, the semiconductor device 100 may be manufactured. The studs 185 may not be formed on the dummy vertical structures 180, and upper surfaces of the dummy vertical structures 180 may be covered with the third cell region insulating layer 196 additionally formed.

When an insulating layer such as the third cell region insulating layer 196 is formed, hydrogen may be present in the insulating layer. When the cell interconnection structure including the studs 185 is formed, such hydrogen may be diffused to a region below the horizontal insulating layer 150 and may hydrogen-passivate the lower structure disposed below the horizontal insulating layer 150. In the semiconductor device 100, by forming vertical dummy structures 180 penetrating through the horizontal insulating layer 150 acting as a hydrogen barrier, a hydrogen diffusion path may be secured. Accordingly, defects in the lower structure including the first channel structures CH may be addressed.

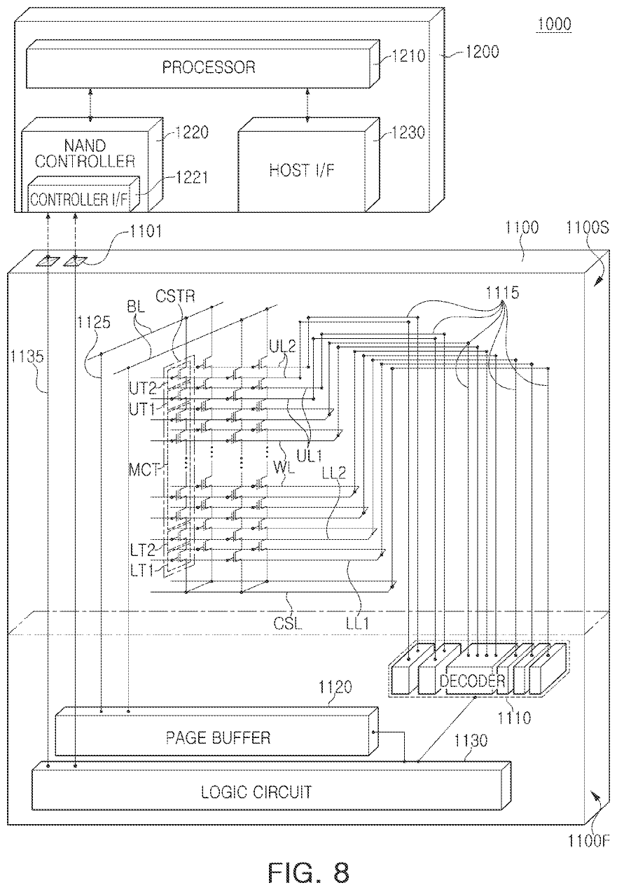

FIG. 8 is a view illustrating an example of a data storage system including a semiconductor device.

Referring to FIG. 8, a data storage system 1000 includes a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example implementation with reference to FIGS. 1 to 6. The semiconductor device 1100 may include a first structure 1100F and a second structure 1100S on the first structure 1100F. In some implementations, the first structure 1100F is disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied.

In some implementations, the upper transistors UT1 and UT2 include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In some implementations, the lower transistors LT1 and LT2 include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In some implementations, the data storage system 1000 includes a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

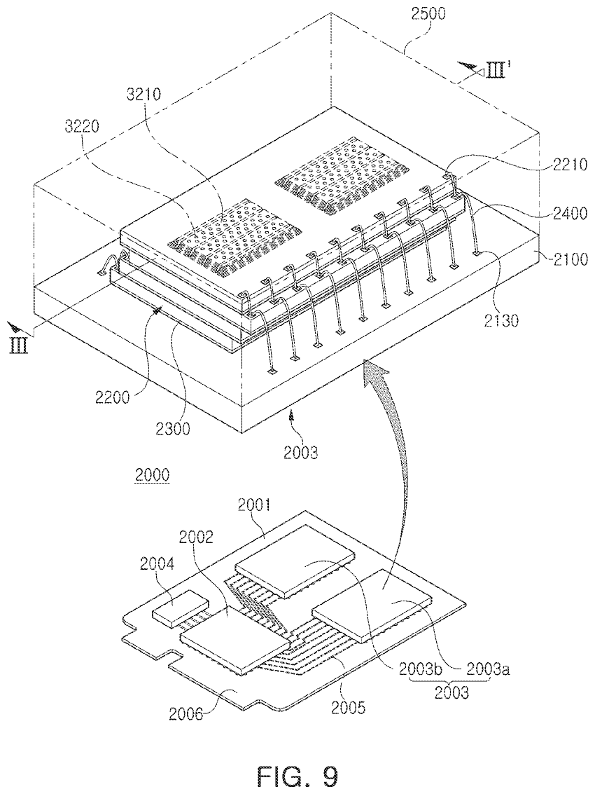

FIG. 9 is a perspective view illustrating an example of a data storage system including a semiconductor device.

Referring to FIG. 9, a data storage system 2000 includes a main board 2001, a controller 2002 mounted on the main board 2001, one or more semiconductor packages 2003, and a DRAM 2004. The semiconductor package 2003 and the DRAM 2004 are connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In some implementations, the data storage system 2000 communicates with an external host according to one of interfaces from among universal serial bus (USB), peripheral component interconnect express (PCI-Express), serial advanced technology attachment (SATA), M-Phy for universal flash storage (UFS). In some implementations, the data storage system 2000 operates by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 8. Each of the semiconductor chips 2200 may include gate stack structures 3210 and channel structures 3220. Each of the semiconductor chips 2200 may include the semiconductor device described in the aforementioned example implementation with reference to FIGS. 1 to 6.

In some implementations, the connection structure 2400 is configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In some implementations, in each of the first and second semiconductor packages 2003a and 2003b, the semiconductor chips 2200 are electrically connected to each other by a connection structure including a through-electrode (TSV) instead of the connection structure 2400 of a bonding wire method.

In some implementations, the controller 2002 and the semiconductor chips 2200 are included in a single package. In some implementations, the controller 2002 and the semiconductor chips 2200 are mounted on an interposer substrate different from the main board 2001, and the controller 2002 and the semiconductor chips 2200 may be connected to each other by interconnection formed on the interposer substrate.

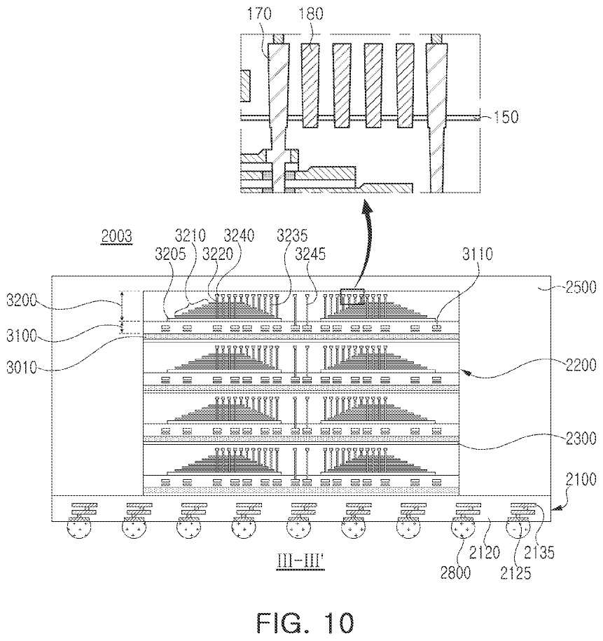

FIG. 10 is a cross-sectional view illustrating an example of a semiconductor package, illustrating an example implementation of the semiconductor package 2003 in FIG. 9 taken along line III-III′.

Referring to FIG. 10, in the semiconductor package 2003, the package substrate 2100 is implemented as a printed circuit substrate. The package substrate 2100 includes a package substrate body portion 2120, package upper pads 2130 disposed on an upper surface of the package substrate body portion 2120 (see FIG. 9), lower pads 2125 disposed on the lower surface of the package substrate body portion 2120 or exposed through the lower surface, and internal interconnections 2135 electrically connecting the upper pads 2130 to the lower pads 2125 in the package substrate body portion 2120. The lower pads 2125 are connected to the interconnection patterns 2005 of the main board 2001 of the data storage system 2000 through the conductive connection portions 2800 as illustrated in FIG. 9.

Each of the semiconductor chips 2200 may include a semiconductor substrate 3010 and a first structure 3100 and a second structure 3200 stacked in order on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 penetrating through the gate stack structure 3210, bitlines 3240 electrically connected to the channel structures 3220, and contact plugs 3235 electrically connected to the wordlines WL (see FIG. 8) of the gate stack structure 3210. As described above with reference to FIGS. 1 to 6, in each of the semiconductor chips 2200, the dummy vertical structures 180 penetrating through the horizontal insulating layer 150 may be disposed around the contact plugs 170.

Each of the semiconductor chips 2200 may include a through-interconnection 3245 electrically connected to the peripheral interconnections 3110 of the first structure 3100 and extending into the second structure 3200. The through-interconnection 3245 may be disposed on an external side of the gate stack structure 3210 and may further be disposed to penetrate through the gate stack structure 3210. Each of the semiconductor chips 2200 may further include an input/output pad 2210 (see FIG. 9) electrically connected to the peripheral interconnections 3110 of the first structure 3100.

According to the aforementioned example implementations, by including the dummy vertical structures penetrating through the horizontal insulating layer disposed between the memory gate electrodes and the upper select gate electrode, a semiconductor device having improved reliability and a data storage system including the same may be provided.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure, the first semiconductor structure including a substrate, a plurality of circuit devices on the substrate, and a plurality of circuit interconnection lines on the circuit devices; and
a second semiconductor structure on the first semiconductor structure, the second semiconductor structure including a first region and a second region,
wherein the second semiconductor structure includes
a plate layer;
a plurality of gate electrodes, the plurality of gate electrodes including lower select gate electrodes, memory gate electrodes, and upper select gate electrodes stacked in order from the plate layer in a first direction perpendicular to an upper surface of the plate layer, wherein the lower select gate electrodes, the memory gate electrodes, and the upper select gate electrodes are spaced apart from each other;
a horizontal insulating layer between the memory gate electrodes and the upper select gate electrode;
a plurality of first channel structures extending through the lower select gate electrode and the memory gate electrodes in the first direction in the first region;
a plurality of connection pads extending through the horizontal insulating layer and connected to the first channel structures;
a plurality of second channel structures extending through the upper select gate electrode, connected to the connection pads, and electrically connected to the plurality of first channel structures, respectively, in the first region;
a plurality of contact plugs extending through at least a portion of the plurality of gate electrodes in the first direction in the second region and electrically connecting the plurality of gate electrodes to a portion of the circuit interconnection lines; and
a plurality of dummy vertical structures around the plurality of contact plugs in the second region, the plurality of dummy vertical structures extending through the horizontal insulating layer in the first direction,
wherein lower ends of the plurality of dummy vertical structures are on a first level, and lower ends of the plurality of contact plugs are on a second level that is lower than the first level.

2. The semiconductor device of claim 1, wherein the second semiconductor structure includes:
a plurality of cell interconnection structures connected to the plurality of contact plugs; and
a cell region insulating layer covering upper surfaces of the plurality of dummy vertical structures.

3. The semiconductor device of claim 1, wherein upper ends of the plurality of dummy vertical structures and upper ends of the plurality of contact plugs are on a substantially same level.

4. The semiconductor device of claim 1, wherein the first level is higher than a third level of an uppermost surface of the memory gate electrodes.

5. The semiconductor device of claim 1, wherein the first level is between a lower surface of the horizontal insulating layer and an uppermost surface of the memory gate electrodes.

6. The semiconductor device of claim 1, wherein the plurality of dummy vertical structures extend through a portion of the memory gate electrodes.

7. The semiconductor device of claim 1, wherein the plurality of dummy vertical structures include a conductive material.

8. The semiconductor device of claim 1, wherein the plurality of dummy vertical structures and the contact plugs include a same material.

9. The semiconductor device of claim 1, wherein a diameter of each dummy vertical structure of the plurality of dummy vertical structures is equal to or smaller than a diameter of each contact plug of the plurality of contact plugs.

10. The semiconductor device of claim 1, wherein the horizontal insulating layer includes nitride.

11. The semiconductor device of claim 1, wherein each contact plug of the plurality of contact plugs includes a vertical extension portion extending in the first direction and at least one horizontal extension portion extending horizontally from the vertical extension portion, and each contact plug of the plurality of contact plugs is in contact with one gate electrode of the plurality of gate electrodes.

12. The semiconductor device of claim 1,
wherein the plurality of gate electrodes form a first step structure having a level decreasing in the first direction and a second step structure having a level increasing in the first direction in the second region, and
wherein the plurality of contact plugs extend through the first step structure.

13. A semiconductor device, comprising:
a plate layer;
a plurality of gate electrodes, wherein the plurality of gate electrodes are stacked and spaced apart from each other on the plate layer in a first direction perpendicular to an upper surface of the plate layer, and the plurality of gate electrodes include first gate electrodes and a second gate electrode on the first gate electrodes;
a horizontal insulating layer between the first gate electrodes and the second gate electrode, the horizontal insulating layer including nitride;
a plurality of first channel structures extending through the first gate electrodes in the first direction;
a plurality of second channel structures extending through the second gate electrode in the first direction, the plurality of second channel structures electrically connected to the plurality of first channel structures, respectively;
a plurality of contact plugs extending through the horizontal insulating layer in the first direction, the plurality of contact plugs connected to the plurality of gate electrodes, respectively;
a plurality of dummy vertical structures extending through the horizontal insulating layer in the first direction and around the plurality of contact plugs; and
a cell region insulating layer covering upper surfaces of the plurality of dummy vertical structures.

14. The semiconductor device of claim 13, wherein a length of each dummy vertical structure of the plurality of dummy vertical structures in the first direction is smaller than a length of each contact plug of the plurality of contact plugs in the first direction.

15. The semiconductor device of claim 13, wherein lower ends of the plurality of dummy vertical structures are on a level equal to or lower than a level of a lower surface of the horizontal insulating layer.

16. The semiconductor device of claim 13, wherein lower ends of the plurality of dummy vertical structures are on a level lower than a level of lower ends of the plurality of second channel structures.

17. The semiconductor device of claim 13, wherein upper ends of the plurality of dummy vertical structures are on a level higher than a level of an upper surface of the second gate electrode.

18. The semiconductor device of claim 13, wherein each contact plug of the plurality of contact plugs has a bent portion of which a width changes below the horizontal insulating layer.

19. A data storage system, comprising:
a semiconductor storage device, the semiconductor storage device including a first semiconductor structure, the first semiconductor structure including a plurality of circuit devices, a second semiconductor structure on one surface of the first semiconductor structure, and an input/output pad electrically connected to the plurality of circuit devices; and
a controller electrically connected to the semiconductor storage device through the input/output pad, the controller configured to control the semiconductor storage device,
wherein the second semiconductor structure includes:
a plate layer;
a plurality of gate electrodes, the plurality of gate electrodes stacked and spaced apart from each other on the plate layer in a first direction perpendicular to an upper surface of the plate layer, and the plurality of gate electrodes including first gate electrodes and a second gate electrode on the first gate electrodes;
a horizontal insulating layer between the first gate electrodes and the second gate electrode, the horizontal insulating layer including nitride;
a plurality of first channel structures extending through the first gate electrodes in the first direction;
a plurality of second channel structures extending through the second gate electrode in the first direction, the plurality of second channel structures electrically connected to the first channel structures, respectively;
a plurality of contact plugs extending through the horizontal insulating layer in the first direction, the plurality of contact plugs connected to the gate electrodes, respectively;
a plurality of dummy vertical structures extending through the horizontal insulating layer in the first direction and around the plurality of contact plugs; and
a cell region insulating layer covering upper surfaces of the plurality of dummy vertical structures,
wherein the plurality of dummy vertical structures and the plurality of contact plugs include a same material, and the plurality of dummy vertical structures have a length different from a length of the plurality of contact plugs.

20. The data storage system of claim 19, wherein lower ends of the plurality of dummy vertical structures are on a level between the second gate electrode and the horizontal insulating layer.
